(19) United States
(12) Patent Application Publication
(10) Pub. No.: US 2018/0166426 A1
(43) Pub. Date: Jun. 14, 2018

(54) SEMICONDUCTOR STRUCTURE AND A MANUFACTURING METHOD THEREOF

(71) Applicant: NANYA TECHNOLOGY CORPORATION, Taoyuan City (TW)

(72) Inventor: PO CHUN LIN, CHANGHUA CITY (TW)

(21) Appl. No.: 15/378,911

(22) Filed: Dec. 14, 2016

(51) Int. Cl. H01L 25/10; H01L 25/00; H01L 23/00; H01L 23/31; H01L 21/48; H01L 21/56

(52) U.S. Cl. CPC H01L 25/105; H01L 25/50; H01L 24/16; H01L 23/3185; H01L 2224/16227; H01L 21/563; H01L 2225/1023; H01L 2225/1058; H01L 2225/1094; H01L 21/4853

(57) ABSTRACT

A semiconductor structure includes a first package including a substrate and a die disposed over the substrate and electrically connected to the substrate by a first conductive bump; a second package disposed over the first package and electrically connected to the substrate by a second conductive bump; and an adhesive disposed between the die and the second package.

### TECHNICAL FIELD

The present disclosure relates to a semiconductor structure, and particularly relates to a package on package (PoP) structure. A package is disposed over another package, and an adhesive is disposed between the packages. Further, a method of manufacturing a semiconductor structure comprises disposing an adhesive between packages.

### DISCUSSION OF THE BACKGROUND

Semiconductor devices are essential for many modern applications. With the advancement of electronic technology, semiconductor devices are becoming smaller in size while having greater functionality and greater amounts of integrated circuitry. Due to the miniaturized scale of semiconductor devices, package on package (PoP) is now widely used for manufacturing. Numerous manufacturing steps are undertaken in the production of such packaging structure.

The manufacturing of semiconductor devices using package on package is becoming more complicated. The semiconductor device is assembled with a number of integrated components including various materials with differences in thermal properties. Since many components with different materials are combined, the complexity of the manufacturing operations of the semiconductor device is increased. Accordingly, there is a continuous need to improve the manufacturing process of semiconductor devices and address the above complexities.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY

One aspect of the present disclosure provides a semiconductor structure comprising a first package including a substrate and a die disposed over the substrate and electrically connected to the substrate by a first conductive bump; a second package disposed over the first package and electrically connected to the substrate by a second conductive bump; and an adhesive disposed between the die and the second package.

In some embodiments, the die is attached to the second package by the adhesive.

In some embodiments, the adhesive is thermally conductive or has an equivalent thermal conductivity of about 0.01 W/(m·K) to about 100 W/(m·K).

In some embodiments, the adhesive includes aluminum, silver, carbon, or particle with thermal conductivity substantially greater than or equal to 25 W/(m·K).

In some embodiments, the die, the first conductive bump and the second conductive bump are disposed between the substrate and the second package.

In some embodiments, the die is surrounded by the second conductive bump.

In some embodiments, the substrate includes a first surface and a second surface opposite to the first surface, and the first conductive bump and the second conductive bump are disposed over the first surface.

In some embodiments, the substrate includes a third conductive bump disposed over the second surface.

In some embodiments, the semiconductor structure further comprises a circuit board bonded with the substrate by the third conductive bump.

In some embodiments, the first conductive bump is surrounded by an underfill material.

In some embodiments, the die includes a third surface and a fourth surface opposite to the third surface, the adhesive is disposed over the third surface, and the first conductive bump is disposed over the fourth surface.

In some embodiments, the die is encapsulated by a molding, and the adhesive is disposed over the molding.

In some embodiments, a height of the second conductive bump is substantially greater than a thickness of the die.

Another aspect of the present disclosure provides a method of manufacturing a semiconductor structure comprising providing a first package including a substrate and a die disposed over the substrate and electrically connected to the substrate by a first conductive bump; providing a second package including a second conductive bump; disposing an adhesive over the die or the second package; and bonding the second package with the substrate by the second conductive bump, wherein the adhesive is disposed between the die and the second package.

In some embodiments, the adhesive is disposed by coating or dispensing.

In some embodiments, the adhesive is in contact with the die and the second package when the second conductive bump is bonded with the substrate.

In some embodiments, the adhesive is configured to conduct heat from the die towards the second package.

In some embodiments, the semiconductor structure is heated after the bonding of the second package with the substrate.

In some embodiments, a curvature of the second package is substantially the same as a curvature of the substrate.

In some embodiments, the method further comprises aligning the second package with the substrate.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a semiconductor structure in accordance with some embodiments of the present disclosure.

FIG. 2 is a schematic cross-sectional view of a semiconductor structure disposed over a circuit board in accordance with some embodiments of the present disclosure.

FIG. 3 is a schematic cross-sectional view of a semiconductor structure including a molding in accordance with some embodiments of the present disclosure.

FIG. 4 is a schematic cross-sectional view of a semiconductor structure including a molding and a via within the molding in accordance with some embodiments of the present disclosure.

FIG. 5 is a flow chart of a method of manufacturing a semiconductor structure in accordance with some embodiments of the present disclosure.

FIGS. 6 to 11 are schematic views of a process of manufacturing the semiconductor structure by the method of FIG. 5 in accordance with some embodiments of the present disclosure.

FIG. 12 is a table showing a relationship between a curvature, a package size and a warpage of a semiconductor structure.

FIG. 13 is a graph showing a relationship between a warpage and a package size of a semiconductor structure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor structure comprising an adhesive disposed between a first package and a second package. Also, the present disclosure is directed to a method of manufacturing a semiconductor structure comprising disposing an adhesive between a first package and a second package. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

A semiconductor structure is manufactured by several processes. A die or chip is disposed over a substrate to become a first package, and then a second package is disposed over the first package to form a package on package (PoP) structure. Such semiconductor structure then undergoes thermal processes such as reflowing. Various components are involved in the thermal processes. Different materials may have different coefficients of thermal expansion (CTEs). Unequal CTEs between various components can result in a warpage of the semiconductor structure after the thermal processes. The semiconductor structure may be curved or bent after thermal processes. As a result, some electrical connectors over the second package may not be able to contact with bond pads on the first package. Cold joints may occur and cause failure of the electrical connection between the first package and the second package.

In the present disclosure, a semiconductor structure is disclosed. The semiconductor structure comprises a first package, a second package disposed over the first package, and an adhesive disposed between the first package and the second package. The first package is attached to the second package by the adhesive. Such attachment can strengthen the bonding or electrical connection between the first package and the second package.

Further, the semiconductor structure may be curved or bent after thermal processes such as reflowing, and thus the bonding or electrical connection between the first package and the second package may be weakened or even broken. Such disposing of the adhesive between the first package and the second package can reduce or prevent fracture of the bonding caused by the warpage of the semiconductor structure after thermal processes. As a result, a cold joint between the first package and the second package can be reduced or prevented. Accordingly, reliability of a semiconductor structure can be improved.

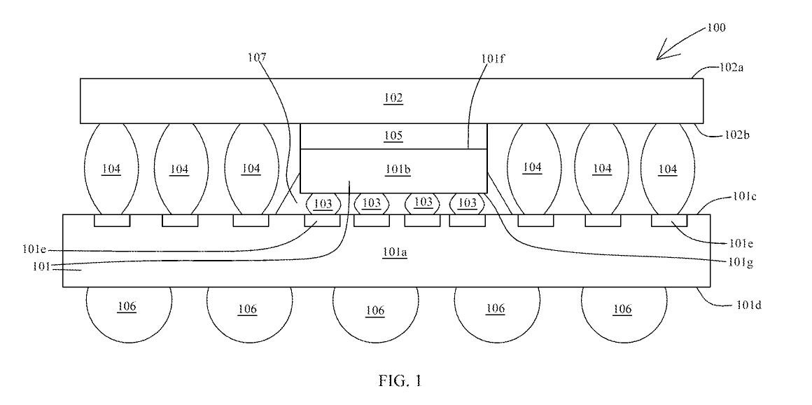

FIG. 1 is a cross-sectional view of a semiconductor structure 100 in accordance with some embodiments of the present disclosure. In some embodiments, the semiconductor structure 100 includes a first package 101, a second package 102 disposed over the first package 101, and an adhesive 105 disposed between the first package 101 and the second package 102. In some embodiments, the first package 101 includes a substrate 101a and a die 101b disposed over the substrate 101a.

In some embodiments, the semiconductor structure 100 is a semiconductor package or a part of the semiconductor package. In some embodiments, the semiconductor structure 100 is a package on package (PoP) structure. In some embodiments, the semiconductor structure 100 is a flip chip package.

In some embodiments, the substrate 101a of the first package 101 is a semiconductive substrate. In some embodiments, the substrate 101a is a wafer. In some embodiments, the substrate 101a includes semiconductive material such as silicon, germanium, gallium, arsenic, and combinations thereof. In some embodiments, the substrate 101a is a silicon substrate. In some embodiments, the substrate 101a includes material such as ceramic, glass or the like. In some embodiments, the substrate 101a includes organic material. In some embodiments, the substrate 101a is a glass substrate. In some embodiments, the substrate 101a is a packaging substrate. In some embodiments, the substrate 101a has a quadrilateral, rectangular, square, polygonal or any other suitable shape.

In some embodiments, the substrate 101a is fabricated with a predetermined functional circuit thereon. In some embodiments, the substrate 101a includes several conductive traces and several electrical components such as transistor, diode, etc. disposed within the substrate 101a.

In some embodiments, the substrate 101a includes a first surface 101c and a second surface 101d opposite to the first surface 101c. In some embodiments, the first surface 101c is a back side or an inactive side. In some embodiments, the second surface 101d is a front side or an active side where the circuits or electrical components are disposed thereon.

In some embodiments, several pads 101e are disposed over the substrate 101a. In some embodiments, the pad 101e is disposed over or within the first surface 101c of the substrate 101a. In some embodiments, the pad 101e is electrically connected to a circuitry or an electrical component in the substrate 101a. In some embodiments, the pad 101e is electrically connected with a circuitry external to the substrate 101a so that the circuitry in the substrate 101a can electrically connect to the circuitry external to the substrate 101a through the pad 101e. In some embodiments, the pad 102 is configured to receive a conductive structure. In some embodiments, the pad 101e is a die pad or a bond pad. In some embodiments, the pad 101e includes gold, silver, copper, nickel, tungsten, aluminum, palladium or alloys thereof.

In some embodiments, the die 101b is disposed over the substrate 101a and electrically connected to the substrate 101a. In some embodiments, the die 101b is fabricated with a predetermined functional circuit within the die 101b produced by photolithography operations. In some embodiments, the die 101b is singulated from a semiconductive wafer by a mechanical or laser blade. In some embodiments, the die 101b comprises a variety of electrical circuits suitable for a particular application. In some embodiments, the electrical circuits include various devices such as transistors, capacitors, resistors, diodes or the like. In some embodiments, the die 101b comprises of any one of various known types of semiconductor devices such as accelerated processing unit (APU), memories (such as SRAMS, flash memories, etc.), microprocessors, application-specific integrated circuits (ASICs), digital signal processors (DSPs), or the like. In some embodiments, the die 101b is a logic device die or the like. FIG. 1 illustrates that the semiconductor structure 100 includes one die 101b, however it is understood that the semiconductor structure 100 can include more than one die 101b. It is not intended to limit a number of dies in the semiconductor structure 100.

In some embodiments, the die 101b includes a third surface 101f and a fourth surface 101g opposite to the third surface 101f. In some embodiments, the third surface 101f is a back side or an inactive side. In some embodiments, the fourth surface 101g is a front side or an active side where the circuits or electrical components are disposed thereon.

In some embodiments, the die 101b is electrically connected to the substrate 101a by a first conductive bump 103. In some embodiments, the first conductive bump 103 is disposed between the substrate 101a and the die 101b. In some embodiments, the first conductive bump 103 is disposed over the first surface 101c of the substrate 101a. In some embodiments, the first conductive bump 103 is disposed over the fourth surface 101g of the die 101b. In some embodiments, the first conductive bump 103 bonds with some of the pads 101e. In some embodiments, the circuitry in the substrate 101a is electrically connected to the circuitry in the die 101b through the first conductive bump 103 and some of the pads 101e.

In some embodiments, the first conductive bump 103 includes conductive material such as solder, copper, nickel, or gold. In some embodiments, the first conductive bump 103 is a solder ball, a ball grid array (BGA) ball, controlled collapse chip connection (C4) bump, microbump, a pillar or the like. In some embodiments, the first conductive bump 103 has a spherical, hemispherical or cylindrical shape.

In some embodiments, the first conductive bump 103 is surrounded by an underfill material 107. In some embodiments, the underfill material 107 surrounds a periphery of the die 101b and encapsulates the first conductive bump 103. In some embodiments, the underfill material 107 is configured to protect the first conductive bump 103 or electrical connection between the die 101b and the substrate 101a. In some embodiments, the underfill material 107 includes polymer, epoxy, or the like.

In some embodiments, the second package 102 is disposed over the first package 101 and electrically connected to the substrate 101a. In some embodiments, the second package 102 is a semiconductor package. In some embodiments, the second package 102 is a flip chip package.

In some embodiments, the second package 102 includes a fifth surface 102a and a sixth surface 102b opposite to the fifth surface 102a. In some embodiments, the fifth surface 102a is a back side or an inactive side. In some embodiments, the sixth surface 102b is a front side or an active side, upon which the circuits or electrical components are disposed.

In some embodiments, the second package 102 is electrically connected to the substrate 101a by a second conductive bump 104. In some embodiments, the second conductive bump 104 is disposed between the second package 102 and the substrate 101a of the first package 101. In some embodiments, the second conductive bump 104 is disposed over the sixth surface 102b. In some embodiments, the second conductive bump 104 is disposed over the first surface 101c of the substrate 101a. In some embodiments, the die 101b and the first conductive bump 103 are surrounded by the second conductive bump 104. In some embodiments, the second conductive bump 104 bonds with some of the pads 101e. In some embodiments, the circuitry in the second package 102 is electrically connected to the circuitry in the substrate 101a through the second conductive bump 104 and some of the pads 101e.

In some embodiments, the second conductive bump 104 includes conductive material such as solder, copper, nickel, or gold. In some embodiments, the second conductive bump 104 is a solder ball, a ball grid array (BGA) ball, controlled collapse chip connection (C4) bump, microbump, a pillar, or the like. In some embodiments, the second conductive bump 104 has a spherical, hemispherical or cylindrical shape. In some embodiments, a height of the second conductive bump 104 is substantially greater than a thickness of the die 101b.

In some embodiments, a third conductive bump 106 is disposed over the substrate 101a. In some embodiments, the third conductive bump 106 is disposed over the second surface 101d of the substrate 101a. In some embodiments, the third conductive bump 106 includes conductive material such as solder, copper, nickel, or gold. In some embodiments, the third conductive bump 106 is a solder ball, a ball grid array (BGA) ball, controlled collapse chip connection (C4) bump, microbump, a pillar or the like. In some embodiments, the third conductive bump 106 has a spherical, hemispherical or cylindrical shape.

In some embodiments, the adhesive 105 is disposed between the die 101b and the second package 102. In some embodiments, the adhesive 105 is disposed over the third surface 101f of the die 101b. In some embodiments, the adhesive 105 is disposed between the sixth surface 102b of the second package 102 and the third surface 101f of the die 101b. In some embodiments, the die 101b and the second package 102 are attached to each other by the adhesive 105. In some embodiments, the adhesive 105 is in contact with the die 101b and the second package 102 when the second conductive bump 104 is bonded with the substrate 101a or some pads 101e of the substrate 101a. In some embodiments, the adhesive 105 is surrounded by the second conductive bump 104 and the die 101b. In some embodiments, the die 101b, the first conductive bump 103, the second conductive bump 104, and the adhesive 105 are disposed between the second package 102 and the substrate 101a.

In some embodiments, a total of a thickness of the adhesive 105, the thickness of the substrate 101b, and a height of the first conductive bump 103 is substantially equal to the height of the second conductive bump 104.

In some embodiments, the adhesive 105 is thermally conductive or has an equivalent thermal conductivity of about 0.01 W/(m·K) to about 100 W/(m·K). In some embodiments, the adhesive 105 includes thermally conductive material such as aluminum, silver, carbon, or particle with thermal conductivity substantially greater than or equal to 25 W/(m·K). In some embodiments, the adhesive 105 comprises a resin with low thermal conductivity and a particle with high thermal conductivity. In some embodiments, the equivalent thermal conductivity of the adhesive 105 comprising the resin with low thermal conductivity and the particle with high thermal conductivity is about 0.01 W/(m·K) to about 100 W/(m·K). In some embodiments, the adhesive 105 is configured to conduct heat from the die 101b towards the second package 102. In some embodiments, the heat generated from the die 101b can be dissipated to the surroundings through the adhesive 105.

In some embodiments, the adhesive 105 is configured to provide a force or tension to maintain contact between the second conductive bump 104 and the substrate 101a or some of the pads 101e of the substrate 101a. In some embodiments, the semiconductor structure 100 has a curvature (bending upward or downward), wherein the second package 102 and the substrate 101a are curved or bent, and the adhesive 105 can provide a force to pull the second package 102 towards the substrate 101a or vice versa when the second conductive bump 104 tends to delaminate from the substrate 101a due to the bending of the semiconductor structure 100. As such, the adhesive 105 can strengthen the bonding between the second conductive bump 104 and the substrate 101a, and also can reduce or prevent delamination of the second conductive bump 104 from the substrate 101a or some of the pads 101e.

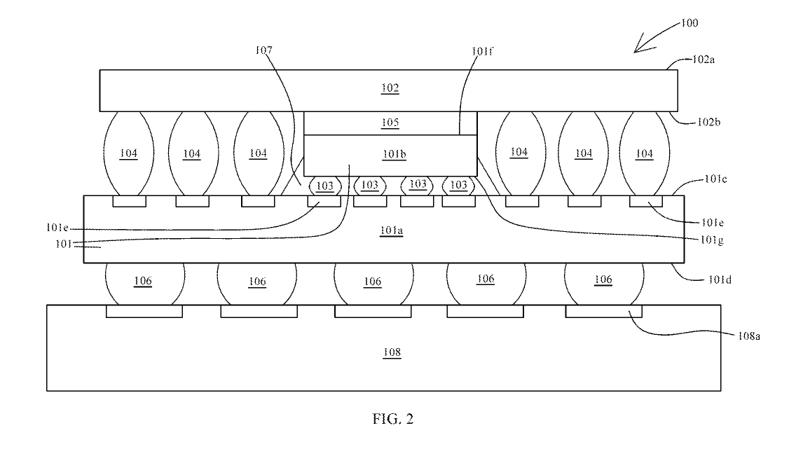

FIG. 2 is a cross-sectional view of the semiconductor structure 100 disposed over a circuit board 108. In some embodiments, the semiconductor structure 100 has a configuration similar to that described above or illustrated in FIG. 1. In some embodiments, the circuit board 108 is a printed circuit board (PCB) or the like.

In some embodiments, the circuit board 108 is bonded with the semiconductor structure 100 by the third conductive bump 106. In some embodiments, the substrate 101a is bonded with the circuit board 108 by the third conductive bump 106. In some embodiments, the second package 102, the die 101b and the substrate 101a are electrically connected to the circuit board 108 through the third conductive bump 106. In some embodiments, the circuit board 108 includes several bond pads 108a disposed over the circuit board 108. In some embodiments, the bond pad 108a is bonded with the third conductive bump 106.

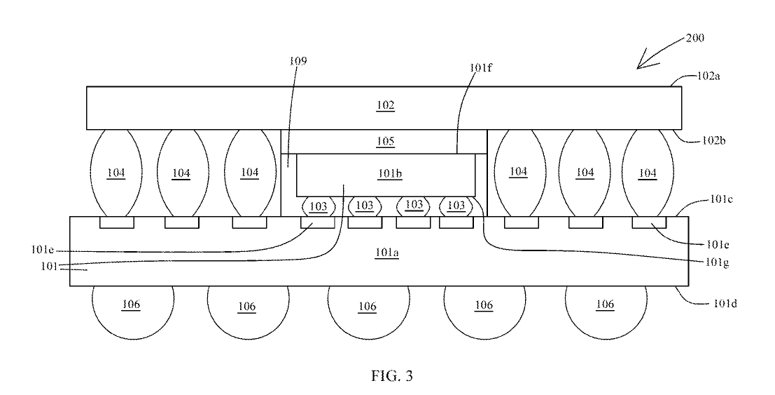

FIG. 3 is a cross-sectional view of a semiconductor structure 200 in accordance with some embodiments of the present disclosure. In some embodiments, the semiconductor structure 200 includes the substrate 101a, the die 101b, the adhesive 105, the first conductive bump 103, the second conductive bump 104, the third conductive bump 106, and the second package 102, which have a configuration similar to that described above or illustrated in FIG. 1 or 2.

In some embodiments, the die 101b is encapsulated by a molding 109, and the adhesive 105 is disposed over the molding 109. In some embodiments, the molding 109 can be a single-layer film or a composite stack. In some embodiments, the molding 109 includes various materials, such as molding compound, molding underfill, epoxy, resin, or the like. In some embodiments, the molding 109 has a high thermal conductivity, a low moisture absorption rate and a high flexural strength. In some embodiments, the molding 109 is a liquid molding compound surrounding the first conductive bump 103.

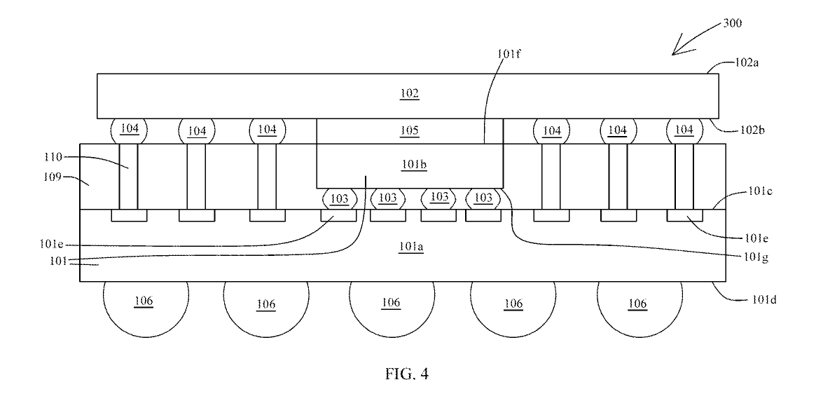

FIG. 4 is a cross-sectional view of a semiconductor structure 300 in accordance with some embodiments of the present disclosure. In some embodiments, the semiconductor structure 200 includes the substrate 101a, the die 101b, the adhesive 105, the first conductive bump 103, the second conductive bump 104, the third conductive bump 106, and the second package 102, which have a configuration similar to that described above or illustrated in FIG. 1 or 2.

In some embodiments, the die 101b, the first conductive bump 103 and a via 110 are surrounded by a molding 109. In some embodiments, the via 110 is conductive or includes conductive material such as copper, aluminum, or silver. In some embodiments, the via 110 is extended through the molding 109. In some embodiments, the via 110 is extended between the pad 101e and the second conductive bump 104. In some embodiments, the via 110 is a through molding via (TMV). In some embodiments, the second package 102 is electrically connected to the substrate 101a through the second conductive bump 104, the via 110 and the pad 101e.

In some embodiments, the molding 109 can be a single-layer film or a composite stack. In some embodiments, the molding 109 includes various materials, such as molding compound, molding underfill, epoxy, resin, or the like. In some embodiments, the molding 109 has a high thermal conductivity, a low moisture absorption rate, and a high flexural strength. In some embodiments, the molding 109 is a liquid molding compound surrounding the first conductive bump 103.

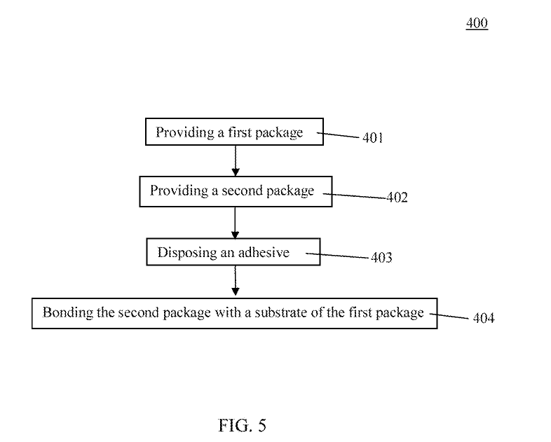

In the present disclosure, a method of manufacturing a semiconductor structure is also disclosed. In some embodiments, the semiconductor structure can be formed by a method 400 of FIG. 5. The method 400 includes a number of operations and the description and illustration are not deemed as a limitation as the sequence of the operations. The method 400 includes a number of steps (401, 402, 403 and 404).

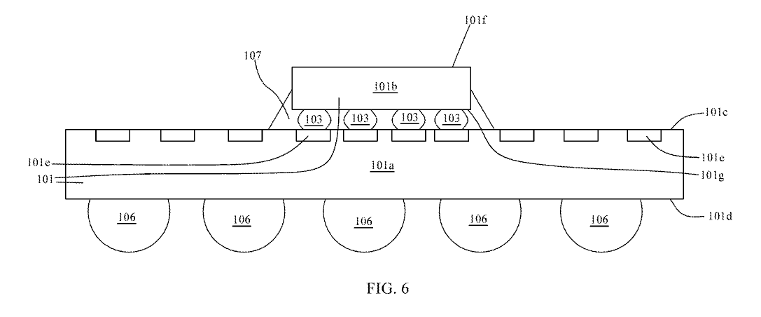

In step 401, a first package 101 is provided or received as shown in FIG. 6. In some embodiments, the first package 101 includes a substrate 101a and a die 101b. In some embodiments, the die 101b is disposed over and electrically connected to the substrate 101a. In some embodiments, the die 101b is electrically connected to the substrate 101a by a first conductive bump 103. In some embodiments, the die 101b bonds with some pads 101e disposed over the substrate 101a.

In some embodiments, the substrate 101a includes a first surface 101c and a second surface 101d opposite to the first surface 101c. In some embodiments, the pad 101e is disposed over the first surface 101c, and a third conductive bump 106 is disposed over the second surface 101d. In some embodiments, the die 101b includes a third surface 101f and a fourth surface 101g. In some embodiments, the first conductive bump 103 is disposed over the fourth surface 101g. In some embodiments, the first conductive bump 103 is disposed between the fourth surface 101g and the first surface 101c. In some embodiments, an underfill material 107 is disposed over the substrate 101a to surround a periphery of the die 101b and the first conductive bump 103.

In some embodiments, the first conductive bump 103 and the third conductive bump 106 are formed by stencil pasting, ball dropping, reflowing, curing or any other suitable processes. In some embodiments, the pad 101e is formed by electroplating or any other suitable process. In some embodiments, the underfill material 107 is disposed by dispensing or any other suitable process. In some embodiments, the substrate 101a, the die 101b, the first conductive bump 103, the third conductive bump 106, and the underfill material 107 have a configuration similar to that described above or illustrated in any one of FIGS. 1-4.

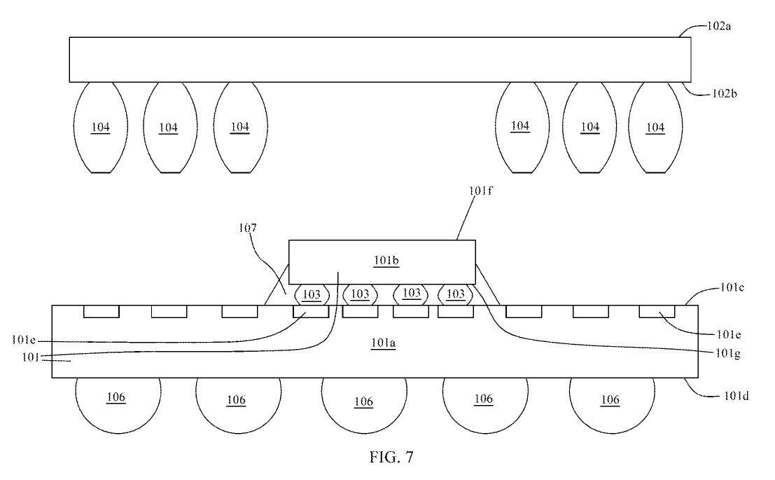

In step 402, a second package 102 is provided or received as shown in FIG. 7. In some embodiments, the second package 102 includes a fifth surface 102a and a sixth surface 102b opposite to the fifth surface 102a. In some embodiments, a second conductive bump 104 is disposed over the sixth surface 102b. In some embodiments, the second package 102 and the second conductive bump 104 have a configuration similar to that described or illustrated in any one of FIGS. 1-4.

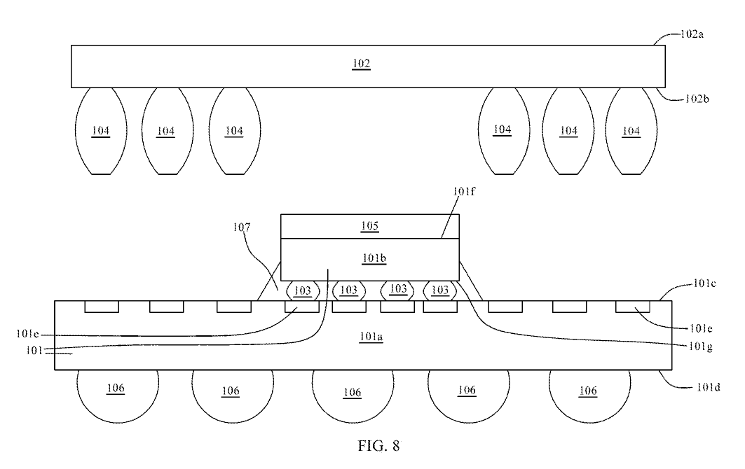

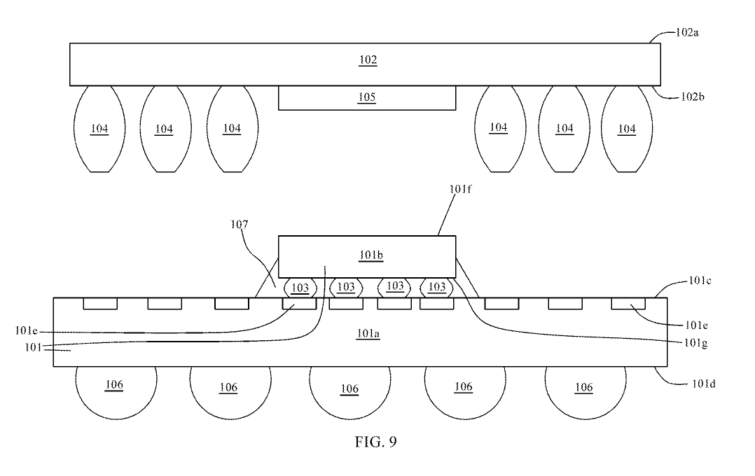

In step 403, an adhesive 105 is disposed over the die 101b or the second package 102 as shown in FIG. 8 or 9. In some embodiments, the adhesive 105 is disposed over the die 101b as shown in FIG. 8. In some embodiments, the adhesive 105 is disposed over the third surface 101f. In some embodiments, the adhesive 105 is disposed over the second package 102 as shown in FIG. 9. In some embodiments, the adhesive 105 is disposed over a portion of the sixth surface 102b, corresponding to the die 101b or the third surface 101f of the die 101b. In some embodiments, the adhesive is disposed by coating or dispensing. In some embodiments, the adhesive 105 has a configuration similar to that described or illustrated in any one of FIGS. 1-4.

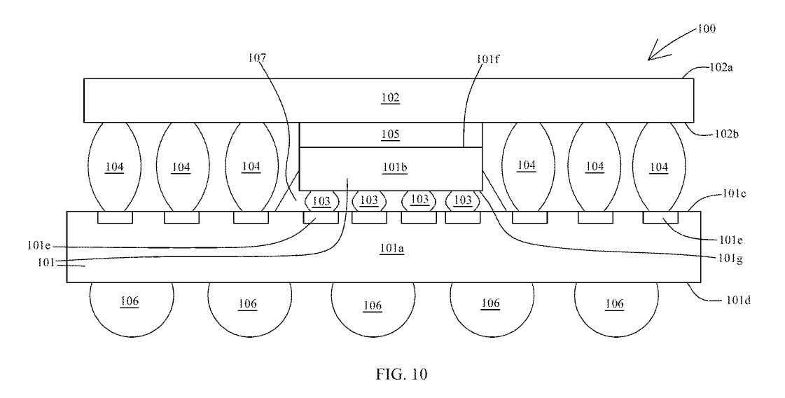

In step 404, the second package 102 is bonded with the substrate 101a of the first package 101 as shown in FIG. 10. In some embodiments, the second package 102 is bonded with the substrate 101a by the second conductive bump 104. In some embodiments, the second conductive bump 104 is disposed over and bonded with the pad 101e over the substrate 101a. In some embodiments, the second package 102 is aligned with the substrate 101a during the bonding, such that the second conductive bump 104 is disposed over the corresponding pad 101e.

In some embodiments, the adhesive 105 is in contact with the die 101b and the second package 102 after the bonding of the second conductive bump 104 with the substrate 101a. In some embodiments, the adhesive 105 is disposed between the die 101b and the second package 102. In some embodiments, the adhesive 105 is configured to conduct heat from the die 101b towards the second package 102.

In some embodiments, a semiconductor structure 100 is formed after the bonding. In some embodiments, the semiconductor structure 100 has a configuration similar to that described above or illustrated in FIG. 1. In some embodiments, the semiconductor structure 100 is heated after the bonding of the second package 102 with the substrate 101a. In some embodiments, the semiconductor structure 100 undergoes thermal processes such as reflowing or curing.

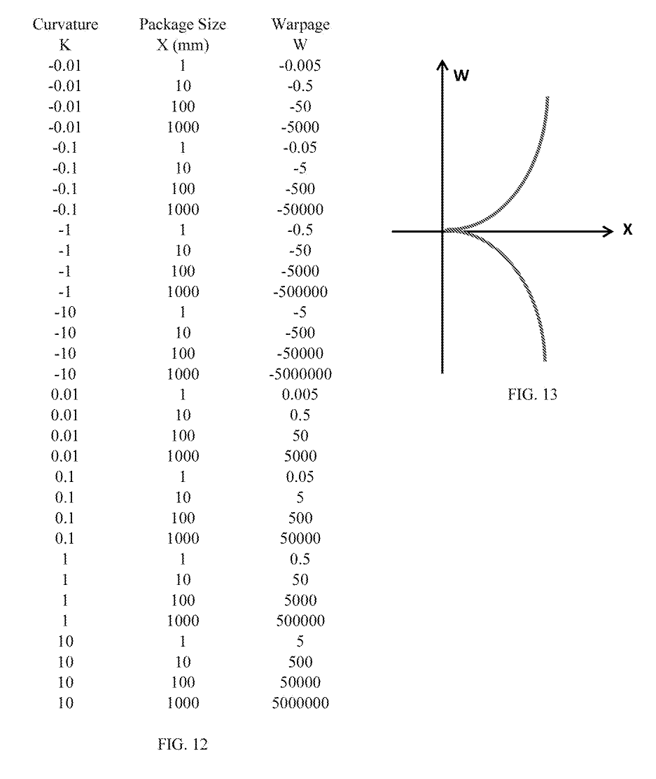

In some embodiments, the semiconductor structure 100 has a curvature (bending upward or downward) after the bonding or the heating. In some embodiments, the second package 102 and the substrate 101a are curved or bent after the bonding or the heating. In some embodiments, a curvature of the second package 102 is substantially the same as a curvature of the substrate 101a. In some embodiments, a warpage of the semiconductor structure 100 is derived from the curvature of the semiconductor structure 100 and an overall package size of the semiconductor structure 100. In some embodiments as shown in FIGS. 12 and 13, the warpage W equals the area of a square with a side length X of the semiconductor structure 100 (that is, the overall package size of the semiconductor structure 100) multiplied by the curvature K of the semiconductor structure 100 and dividing by two (W=X²*K/2). In some embodiments, the positive warpage W or curvature K means the semiconductor structure 100 curves downward, while negative warpage W or curvature K means the semiconductor structure 100 curves upward.

In some embodiments, when the semiconductor structure 100 is curved, the second conductive bump 104 tends to delaminate from the substrate 101a or from the pad 101e. In some embodiments, the adhesive 105 can provide a force or tension to pull the second package 102 towards the substrate 101a or vice versa when the second conductive bump 104 tends to delaminate from the substrate 101a. As such, the adhesive 105 can strengthen the bonding between the second conductive bump 104 and the substrate 101a, and also can reduce or prevent delamination of the second conductive bump 104 from the substrate 101a or some of the pads 101e.

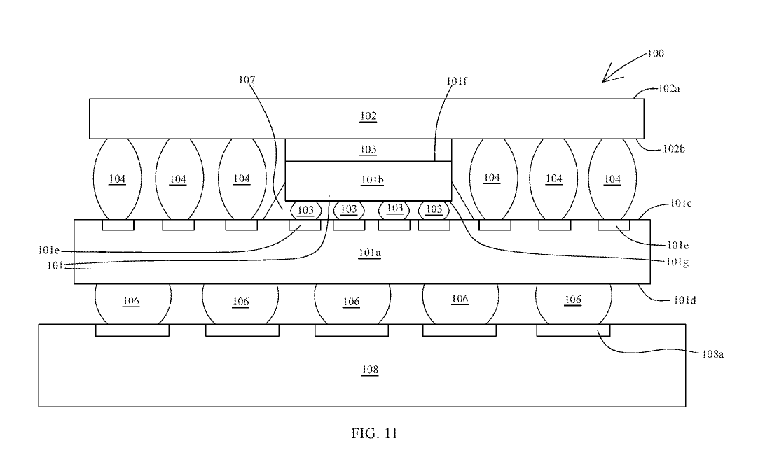

In some embodiments, a circuit board 108 is provided or received as shown in FIG. 11 after the bonding. In some embodiments, the third conductive bump 106 is disposed over and bonded with the circuit board 108. In some embodiments, the third conductive bump 106 is bonded with a bond pad 108a over the circuit board 108. In some embodiments, the circuit board 108 and the bond pad 108a have a configuration similar to that described above or illustrated in FIG. 2.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

1. A semiconductor structure, comprising:
a first package including a substrate and a die disposed over the substrate and electrically connected to the substrate by a first conductive bump;
a second package disposed over the first package and electrically connected to the substrate by a second conductive bump;
an adhesive disposed between the die and the second package; and
a plurality of pads disposed over the substrate and electrically connected to the first conductive bump and the second conductive bump, whereby the substrate electrically connected to the die through the first conductive bump and the plurality of pads, and electrically connected to the second package through the second conductive bump and the plurality of pads;
wherein the die and the first conductive bump are encapsulated by a molding, and the adhesive is disposed over the molding.

2. The semiconductor structure of claim 1, wherein the die is attached to the second package by the adhesive.

3. (canceled)

4. The semiconductor structure of claim 1, wherein the adhesive includes aluminum, silver, carbon, or particle with thermal conductivity substantially greater than or equal to 25 W/(m·K).

5. The semiconductor structure of claim 1, wherein the die, the first conductive bump, and the second conductive bump are disposed between the substrate and the second package.

6. The semiconductor structure of claim 1, wherein the die is surrounded by the second conductive bump.

7. The semiconductor structure of claim 1, wherein the substrate includes a first surface and a second surface opposite to the first surface, and the first conductive bump and the second conductive bump are disposed over the first surface.

8. The semiconductor structure of claim 7, wherein the substrate includes a third conductive bump disposed over the second surface.

9. The semiconductor structure of claim 8, further comprising a circuit board bonded with the substrate by the third conductive bump.

10. The semiconductor structure of claim 1, wherein the first conductive bump is surrounded by an underfill material.

11. The semiconductor structure of claim 1, wherein the die includes a third surface and a fourth surface opposite to the third surface, the adhesive is disposed over the third surface, and the first conductive bump is disposed over the fourth surface.

12. (canceled)

13. The semiconductor structure of claim 1, wherein a height of the second conductive bump is substantially greater than a thickness of the die.

14. A method of manufacturing a semiconductor structure, comprising:
providing a first package including a substrate, a plurality of pads disposed over the substrate, and a die disposed over the plurality of pads and the substrate and electrically connected to the substrate by a first conductive bump and the plurality of pads;
providing a second package including a second conductive bump, the second conductive bump disposed over and bonded with one of the plurality of pad and electrically connected to the substrate by the plurality of pads;
disposing an adhesive over the die or the second package; and
bonding the second package with the substrate by the second conductive bump,
wherein the adhesive is disposed between the die and the second package;
wherein the die and the first conductive bump are encapsulated by a molding, and the adhesive is disposed over the molding.

15. The method of claim 14, wherein the adhesive is disposed by coating or dispensing.

16. The method of claim 14, wherein the adhesive is in contact with the die and the second package when the second conductive bump is bonded with the substrate.

17. The method of claim 14, wherein the adhesive is configured to conduct heat from the die towards the second package.

18. The method of claim 14, wherein the semiconductor structure is heated after the bonding of the second package with the substrate.

19. The method of claim 18, wherein a curvature of the second package is substantially the same as a curvature of the substrate.

20. The method of claim 14, further comprising aligning the second package with the substrate.

21. The semiconductor structure of claim 1, wherein the adhesive is thermally conductive or has an equivalent thermal conductivity of about 0.01 to about 100 W/(m·K).
